(19) United States
(12) Patent Application Publication
(10) Pub. No.: US 2026/0173444 A1
(43) Pub. Date: Jun. 18, 2026

(54) SEMICONDUCTOR DEVICE AND METHOD FOR MANUFACTURING THE SAME

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Kenji KIKUCHI, Komatsu Ishikawa (JP); Kouta TOMITA, Nonoichi Ishikawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/311,031

(22) Filed: Aug. 27, 2025

(30) Foreign Application Priority Data
Dec. 18, 2024 (JP) 2024-223123

(51) Int. Cl. H10D 30/66; H10D 30/01; H10D 62/10; H10D 64/00

(52) U.S. Cl. CPC H10D 30/668; H10D 30/0297; H10D 62/127; H10D 64/112; H10D 64/117

(57) ABSTRACT

A semiconductor device according to an embodiment includes a semiconductor layer, and first to third field plate (FP) insulating films provided in a columnar shape in a first semiconductor region of a first conductivity type in the semiconductor layer and provided with first to third FP electrodes therein, respectively. The second and third FP insulating film is aligned with the first FP insulating film along a second and third direction, respectively. A first distance between the first and second FP electrode is smaller than a second distance between the first and third FP electrode. The first FP insulating film includes a first portion located on a line connecting the first FP electrode and the second FP electrode, and a second portion located on a line connecting the first FP electrode and the third FP electrode and having a dielectric constant higher than that of the first portion.

### CROSS-REFERENCE TO RELATED APPLICATIONS

This application is based upon and claims the benefit of priority from the prior Japanese Patent Application No. 2024-223123, filed on Dec. 18, 2024; the entire contents of which are incorporated herein by reference.

### FIELD

Embodiments described herein relate generally to a semiconductor device and a method for manufacturing the same.

### BACKGROUND

A so-called dot-patterned metal oxide semiconductor field effect transistor (MOSFET) provided with a plurality of columnar field plate electrodes (FP electrodes) is known. In such a semiconductor device such as a MOSFET, a breakdown voltage is preferably high. However, in the dot-patterned MOSFET, a distance between the FP electrode and the gate electrode is not constant. Therefore, in a portion where the distance between the FP electrode and the gate electrode is relatively long, a drift region is not sufficiently depleted as compared with a portion where the distance is relatively short, and a target breakdown voltage may not be secured.

### BRIEF DESCRIPTION OF THE DRAWINGS

FIG. 1 is a plan view of a semiconductor device according to a first embodiment;

FIG. 2 is an enlarged view of FIG. 1;

FIG. 3 is a cross-sectional view of the semiconductor device according to the first embodiment, taken along a U-axis direction in FIG. 1;

FIG. 4 is a cross-sectional view of the semiconductor device according to the first embodiment, taken along a V-axis direction in FIG. 1;

FIG. 5A is a cross-sectional view for explaining an example of a manufacturing process of the semiconductor device according to the first embodiment;

FIG. 5B is a cross-sectional view for explaining an example of the manufacturing process of the semiconductor device according to the first embodiment, subsequent to FIG. 5A;

FIG. 5C is a cross-sectional view for explaining an example of the manufacturing process of the semiconductor device according to the first embodiment, subsequent to FIG. 5B;

FIG. 5D is a schematic plan view of the semiconductor device according to the first embodiment in the manufacturing process illustrated in FIG. 5C;

FIG. 5E is a cross-sectional view for explaining an example of the manufacturing process of the semiconductor device according to the first embodiment, subsequent to FIG. 5C;

FIG. 5F is a cross-sectional view for explaining an example of the manufacturing process of the semiconductor device according to the first embodiment, subsequent to FIG. 5E;

FIG. 5G is a cross-sectional view for explaining an example of the manufacturing process of the semiconductor device according to the first embodiment, subsequent to FIG. 5F;

FIG. 5H is a cross-sectional view for explaining an example of the manufacturing process of the semiconductor device according to the first embodiment, subsequent to FIG. 5G;

FIG. 5I is a cross-sectional view for explaining an example of the manufacturing process of the semiconductor device according to the first embodiment, subsequent to FIG. 5H;

FIG. 6 is a cross-sectional view of the semiconductor device according to a modification of the first embodiment, taken along the U-axis direction in FIG. 1;

FIG. 7 is a cross-sectional view for explaining an example of a manufacturing process of the semiconductor device according to a modification of the first embodiment;

FIG. 8 is a plan view of a semiconductor device according to a second embodiment;

FIG. 9 is an enlarged view of FIG. 8;

FIG. 10 is a cross-sectional view of the semiconductor device according to the second embodiment, taken along a U-axis direction in FIG. 8;

FIG. 11 is a cross-sectional view of the semiconductor device according to the second embodiment, taken along a V-axis direction in FIG. 8;

FIG. 12A is a cross-sectional view for explaining an example of a manufacturing process of the semiconductor device according to the second embodiment;

FIG. 12B is a schematic plan view of the semiconductor device according to the second embodiment in the manufacturing process illustrated in FIG. 12A;

FIG. 12C is a cross-sectional view for explaining an example of the manufacturing process of the semiconductor device according to the first embodiment, subsequent to FIG. 12A;

FIG. 12D is a cross-sectional view for explaining an example of the manufacturing process of the semiconductor device according to the first embodiment, subsequent to FIG. 12C;

FIG. 12E is a cross-sectional view for explaining an example of the manufacturing process of the semiconductor device according to the first embodiment, subsequent to FIG. 12D;

FIG. 12F is a cross-sectional view for explaining an example of the manufacturing process of the semiconductor device according to the first embodiment, subsequent to FIG. 12E;

FIG. 13 is a cross-sectional view of a semiconductor device according to a third embodiment, taken along the U-axis direction in FIG. 8;

FIG. 14 is a cross-sectional view for explaining an example of a manufacturing process of the semiconductor device according to the third embodiment;

FIG. 15 is a plan view of a semiconductor device according to other Modification 1 of the embodiment;

FIG. 16 is a plan view of a semiconductor device according to other Modification 2 of the embodiment;

FIG. 17 is a plan view of a semiconductor device according to other Modification 3 of the embodiment;

FIG. 18 is a plan view of a semiconductor device according to other Modification 4 of the embodiment; and

FIG. 19 is a plan view of a semiconductor device according to other Modification 5 of the embodiment.

### DETAILED DESCRIPTION

A semiconductor device according to an embodiment includes a semiconductor layer, a first electrode, a second electrode, a first semiconductor region of a first conductivity type, a second semiconductor region of a second conductivity type, a third semiconductor region of the first conductivity type, a gate electrode, a first field plate insulating film, a second field plate insulating film, and a third field plate insulating film. The semiconductor layer includes a first main surface and a second main surface. The first electrode is provided on the first main surface. The second electrode is provided on the second main surface. The first semiconductor region is provided inside the semiconductor layer, and electrically connected to the first electrode. The second semiconductor region is provided in the semiconductor layer and is located on the first semiconductor region. The third semiconductor region is provided in the semiconductor layer and is located on the second semiconductor region. The gate electrode is provided in the second semiconductor region via the gate insulating film. The first field plate insulating film is provided in a columnar shape in the first semiconductor region and has a first field plate electrode disposed therein. The second field plate insulating film is provided in a columnar shape in the first semiconductor region, has a second field plate electrode disposed therein, and aligned with the first field plate insulating film along a second direction orthogonal to a first direction from the first main surface toward the second main surface. The third field plate insulating film is provided in a columnar shape in the first semiconductor region, has a third field plate electrode disposed therein, and aligned with the first field plate insulating film along a third direction orthogonal to the first direction and different from the second direction. A first distance between the first field plate electrode and the second field plate electrode is smaller than a second distance between the first field plate electrode and the third field plate electrode. The first field plate insulating film includes a first portion located on a line connecting the first field plate electrode and the second field plate electrode, and a second portion located on a line connecting the first field plate electrode and the third field plate electrode. A dielectric constant of the second portion in the first field plate insulating film is higher than a dielectric constant of the first portion in the first field plate insulating film.

Hereinafter, embodiments according to the present invention will be described with reference to the drawings. The embodiments do not limit the present invention. The drawings are schematic or conceptual, and the ratio of each portion and the like are not necessarily the same as actual ones. In the specification and the drawings, elements similar to those described above with respect to the previously described drawings are denoted by the same reference numerals, and the detailed description thereof is appropriately omitted.

In addition, in the following description, notations of n⁺, n, and n⁻, and p⁺, p, and p⁻ may be used to represent the relative level of impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both the p-type impurity and the n-type impurity are contained in each region, these notations represent the relative level of the net impurity concentration after the impurities have been compensated for. The n type, n⁺ type, and n⁻ type are examples of a first conductivity type in the claims. The p type, p⁺ type, and p⁻ type are examples of a second conductivity type in the claims. Note that in the following description, the n type and the p type may be reversed. That is, the first conductivity type may be the p-type.

In addition, the impurity concentration of the semiconductor region can be measured by, for example, secondary ion mass spectrometry (SIMS). In addition, the relative level of the impurity concentration can also be determined from the level of a carrier concentration obtained by, for example, scanning capacitance microscopy (SCM).

In addition, a dimension such as the thickness of the field plate insulating film can be measured by, for example, analysis of a surface and/or a cross section by a transmission electron microscope (TEM), an energy dispersive X-ray spectroscopy (EDX), or a scanning electron microscope (SEM).

In addition, the composition of the field plate insulating film can be analyzed by, for example, X-ray photoelectron spectroscopy (XPS) or secondary ion mass spectrometry.

Note that terms such as “identical”, “same”, and “equal”, dimensions, values of physical characteristics, and the like, which specify shapes, geometric conditions, physical characteristics, and the degrees thereof, used in the present specification, are interpreted including a range in which similar functions can be expected, without being bound by a strict meaning.

### First Embodiment

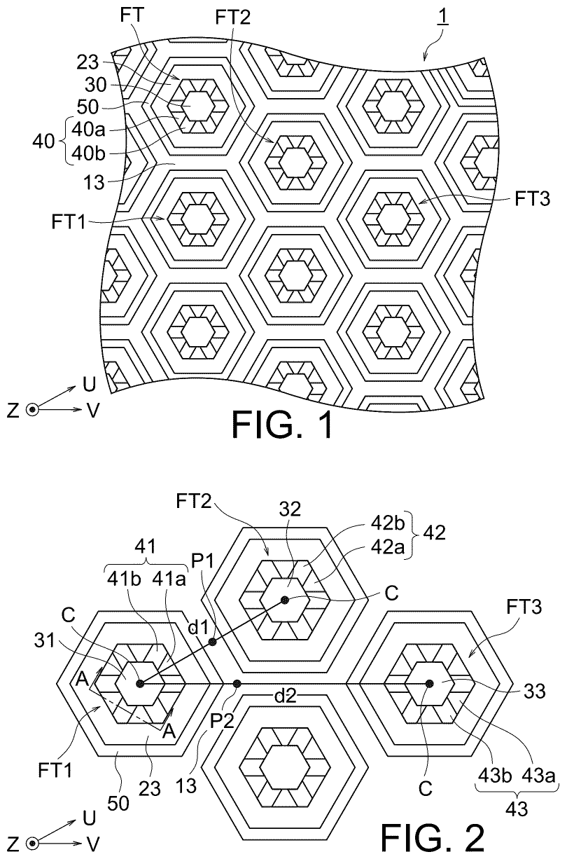

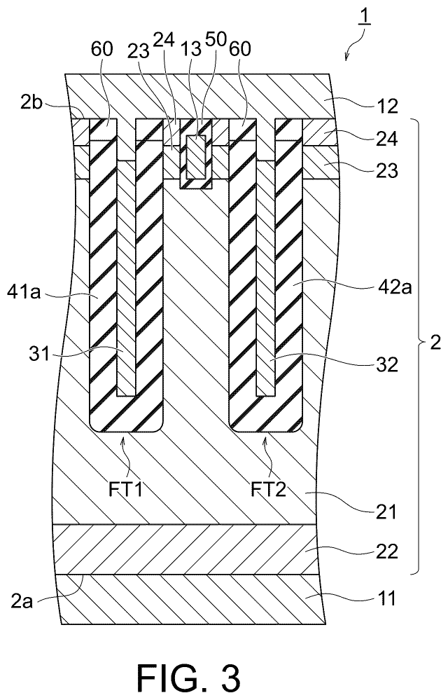

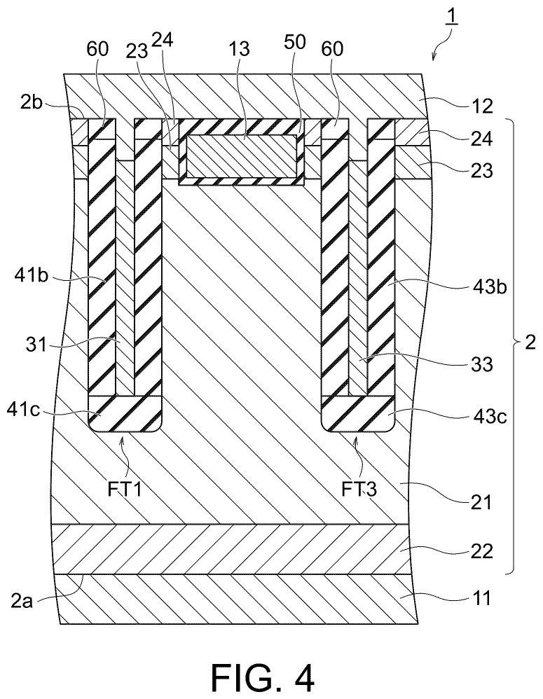

A semiconductor device 1 according to a first embodiment will be described with reference to FIGS. 1 to 4. FIG. 1 is a plan view of the semiconductor device 1 according to the first embodiment. In FIG. 1, a U-axis direction is a direction from an FP trench FT1 toward an FP trench FT2. A V-axis direction is a direction from the FP trench FT1 toward an FP trench FT3. A Z-axis direction is a stacking direction (thickness direction) of the semiconductor device 1. The U-axis direction and the V-axis direction are both orthogonal to the Z-axis direction. Note that, in the Z-axis direction, a source electrode side is also referred to as “upper”, and a drain electrode side is also referred to as “lower”. However, this expression is for convenience and independent of the direction of gravity. The Z-axis direction is a first direction in the claims. The U-axis direction is a second direction in the claims. The V-axis direction is a third direction in the claims. In addition, in FIG. 1, a source electrode 12, a source region 24, and an inter-layer insulating film 60 are omitted. FIG. 2 is an enlarged view of FIG. 1, and illustrates the periphery of the FP trenches FT1, FT2, and FT3 in an enlarged manner. FIG. 3 is a cross-sectional view of the semiconductor device 1 according to the first embodiment, taken along a U-axis direction in FIG. 1. FIG. 4 is a cross-sectional view of the semiconductor device 1 according to the first embodiment, taken along a V-axis direction in FIG. 1; Note that, in FIG. 3, FP electrodes 31 and 32 are illustrated as an FP electrode 30, and in FIG. 4, FP electrodes 31 and 33 are illustrated as the FP electrode 30.

The semiconductor device 1 is, for example, a MOSFET. More specifically, the semiconductor device 1 is a so-called dot-patterned MOSFET including a plurality of field plate electrodes (FP electrodes) provided in a columnar shape, that is, extending in the Z-axis direction. Note that the semiconductor device 1 may be a dot-patterned insulated gate bipolar transistor (IGBT) or the like.

As illustrated in FIG. 1, the semiconductor device 1 includes a plurality of field plate trenches (FP trenches) FT. In each FP trench FT, the FP electrode 30 and a field plate insulating film (FP insulating film) 40 surrounding the FP electrode 30 are provided. As will be described in detail later, each FP insulating film 40 includes a first portion 40a and a second portion 40b having a dielectric constant higher than that of the first portion 40a.

In addition, a semiconductor region (for example, a base region 23) is arranged around the FP insulating film 40, and a gate insulating film 50 is arranged around the semiconductor region. A mesh-shaped gate electrode 13 coupled to each other is provided around the gate insulating film 50.

Next, a cross-sectional structure of the semiconductor device 1 according to the present embodiment will be described.

In the following description, among the plurality of FP trenches FT illustrated in FIG. 1, the FP trench FT1, the FP trench FT2, and the FP trench FT3 will be described. In the present embodiment, the plurality of FP trenches FT, for example, all the FP trenches FT1, FT2, and FT3 have the same configuration.

In addition, as illustrated in FIG. 2, in the following description, in order to distinguish the FP electrodes 30 in the respective FP trenches FT1, FT2, and FT3, the FP electrodes 30 in the FP trenches FT1, FT2, and FT3 are referred to as the FP electrodes 31, 32, and 33, respectively. Similarly, the FP insulating films 40 in the FP trenches FT1, FT2, and FT3 are referred to as FP insulating films 41, 42, and 43, respectively. In addition, the first portions 40a in the FP insulating films 41, 42, and 43 are referred to as first portions 41a, 42a, and 43a, respectively. Similarly, the second portions 40b in the FP insulating films 41, 42, and 43 are referred to as second portions 41b, 42b, and 43b, respectively.

As illustrated in FIGS. 3 and 4, the semiconductor device 1 according to the present embodiment includes a semiconductor layer 2, a drain electrode 11, and a source electrode 12.

The semiconductor layer 2 is provided between the drain electrode 11 and the source electrode 12. The semiconductor layer 2 includes a lower surface (first main surface) 2a and an upper surface (second main surface) 2b opposite to the lower surface 2a. Various semiconductor regions described later and the like are provided in the semiconductor layer 2.

The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). In this case, for example, arsenic (As), phosphorus (P), or antimony (Sb) is used as the n-type impurity, and for example, boron (B) is used as the p-type impurity. Note that the semiconductor layer 2 may be made of a compound semiconductor such as silicon carbide (SiC) or gallium nitride (GaN).

The drain electrode 11 functions as a drain electrode of the MOSFET. The drain electrode 11 is provided on the lower surface 2a of the semiconductor layer 2. The drain electrode 11 is in contact with the drain region 22, and for example, is in ohmic contact with the drain region 22. The drain electrode 11 is an example of a first electrode in the claims. The drain electrode 11 contains at least one of, for example, copper (Cu), titanium (Ti), tungsten (W), and aluminum (Al).

The source electrode 12 functions as a source electrode of the MOSFET. The source electrode 12 is provided on the upper surface 2b of the semiconductor layer 2. The source electrode 12 is in contact with the source region 24, and for example, in ohmic contact with the source region 24. The source electrode 12 is an example of a second electrode in the claims. The source electrode 12 contains at least one of, for example, copper (Cu), titanium (Ti), tungsten (W), and aluminum (Al).

Hereinafter, the configuration in the semiconductor layer 2 will be described.

In the semiconductor layer 2, for example, the drift region 21, the drain region 22, the base region 23, the source region 24, the gate electrode 13, the FP electrodes 30 (FP electrodes 31, 32, and 33), the FP insulating films 40 (FP insulating films 41, 42, and 43), the gate insulating film 50, and the inter-layer insulating film 60 are provided.

The drift region 21 functions as a drift region of the MOSFET. The drift region 21 is disposed on the drain region 22 (above the drain electrode 11). The drift region 21 is, for example, an n⁻ type semiconductor region. The n-type impurity concentration of the drift region 21 is, for example, 1×10¹⁵ cm⁻³ or more and 2×10¹⁶ cm⁻³ or less.

The drain region 22 functions as a drain region of the MOSFET. The drain region 22 is located on the drain electrode 11 and is disposed between the drift region 21 and the drain electrode 11. The drain region 22 is in contact with the drain electrode 11 and is electrically connected to the drain electrode 11. The drain region 22 is, for example, an n⁺-type semiconductor region. An n-type impurity concentration of the drain region 22 is, for example, 1×10¹⁸ cm⁻³ or more and 1×10²¹ cm⁻³ or less.

The drift region 21 and the drain region 22 are examples of a first semiconductor region in the claims. Note that the drain region 22 may not be provided. In this case, the drift region 21 is directly provided on the drain electrode 11, and the drain electrode 11 is electrically connected to the drift region 21. Alternatively, the drift region 21 may not be provided. In this case, for example, the drain region 22 is also provided at the position of the drift region 21.

The base region 23 functions as a base region of the MOSFET. The base region 23 is located on the drift region 21. The base region 23 is, for example, a p-type semiconductor region. The p-type impurity concentration of the base region 23 is, for example, 1×10¹⁶ cm⁻³ or more and 1×10²⁰ cm⁻³ or less. The base region 23 is an example of a second semiconductor region in the claims.

The source region 24 functions as a source region of the MOSFET. The source region 24 is located on the base region 23. The source region 24 is in contact with the source electrode 12 and is electrically connected to the source electrode 12. The source region 24 is, for example, an n⁺-type semiconductor region. The n-type impurity concentration of the source region 24 is, for example, 1×10¹⁸ cm⁻³ or more and 1×10²² cm⁻³ or less. The source region 24 is an example of a third semiconductor region in the claims.

The gate electrode 13 functions as a gate electrode of the MOSFET. The gate electrode 13 is provided in the base region 23 via the gate insulating film 50. The gate electrode 13 is electrically insulated from the semiconductor layer 2 by the gate insulating film 50. The gate electrode 13 is made of, for example, polysilicon containing p-type or n-type impurities. When a voltage is applied to the gate electrode 13, a channel is formed in the base region 23, and carriers flow between the drift region 21 and the source region 24. As a result, the MOSFET is brought into an on-state.

The FP electrode 30 is provided in a columnar shape in the drift region 21 via the FP insulating film 40. In FIG. 3, FP electrodes 31 and 32 are illustrated as an FP electrode 30, and in FIG. 4, FP electrodes 31 and 33 are illustrated as the FP electrode 30. The FP electrode 31, the FP electrode 32, and the FP electrode 33 are examples of a first field plate electrode, a second field plate electrode, and a third field plate electrode, respectively, in the claims.

The FP electrode 30 is electrically insulated from the semiconductor layer 2 by the FP insulating film 40, and is electrically connected to the source electrode 12. In the examples of FIGS. 3 and 4, the source electrode 12 protrudes downward from the upper surface 2b of the semiconductor layer 2 and has a portion in contact with the FP electrode 30. The FP electrode 30 is made of, for example, polysilicon containing p-type or n-type impurities.

In the present embodiment, the FP electrode 30 is provided so as to be adjacent to the base region 23 in addition to the drift region 21. That is, an upper end of the FP electrode 30 is higher than a lower end of the base region 23. Note that the upper end of the FP electrode 30 may be lower than the lower end of the base region 23.

The FP insulating film 40 is provided in a columnar shape in the drift region 21 and has the FP electrode 30 disposed therein. More specifically, the FP insulating film 41 is provided in a columnar shape in the drift region 21 and has the FP electrode 31 disposed therein. The FP insulating film 42 is provided in a columnar shape in the drift region 21 and has the FP electrode 32 disposed therein. The FP insulating film 43 is provided in a columnar shape in the drift region 21 and has the FP electrode 33 disposed therein. The FP insulating film 41, the FP insulating film 42, and the FP insulating film 43 are examples of a first field plate insulating film, a second field plate insulating film, and a third field plate insulating film, respectively, in the claims.

As illustrated in FIG. 1, the FP insulating film 40 includes the first portion 40a and the second portion 40b. As illustrated in FIG. 2, for example, the FP insulating film 41 includes the first portion 41a and the second portion 41b. Note that, in FIG. 3, as the first portion 40a of the FP insulating film 40, the first portion 41a of the FP insulating film 41 and the first portion 42a of the FP insulating film 42 are illustrated. In addition, in FIG. 4, as the second portion 40b of the FP insulating film 40, the second portion 41b of the FP insulating film 41 and the second portion 43b of the FP insulating film 43 are illustrated.

The dielectric constant of the second portion 40b in the FP insulating film 40 is higher than the dielectric constant of the first portion 40a in the FP insulating film 40. For example, the dielectric constant of the second portion 41b in the FP insulating film 41 is higher than the dielectric constant of the first portion 41a in the FP insulating film 41. In the present embodiment, the first portion 40a of the FP insulating film 40 is a silicon oxide film, and the second portion 40b of the FP insulating film 40 is made of a material having a dielectric constant higher than that of the silicon oxide film. The second portion 40b includes, for example, a silicon nitride film. In this case, for example, the relative permittivity of the first portion 41a is about 3.9, and the relative permittivity of the second portion 40b is about 7.0.

In addition, as illustrated in FIG. 4, in the present embodiment, the FP insulating film 40 includes a third portion 40c located below the second portion 40b and disposed on the drift region 21. For example, the FP insulating film 41 includes a third portion 41c located below the second portion 41b and disposed on the drift region 21. In FIG. 4, as the third portion 40c of the FP insulating film 40, the third portion 41c of the FP insulating film 41 and a third portion 43c of the FP insulating film 43 are illustrated. The third portion 40c is made of, for example, the same material as the first portion 40a. The third portion 40c is, for example, a silicon oxide film.

The gate insulating film 50 electrically insulates the gate electrode 13 from the semiconductor layer 2 and the source electrode 12. The gate insulating film 50 contains, for example, a silicon oxide or a silicon nitride.

The inter-layer insulating film 60 is provided on the FP insulating film 40. The inter-layer insulating film 60 contains, for example, a silicon oxide or a silicon nitride. Note that the thickness of the inter-layer insulating film 60 and the position of the lower end of the inter-layer insulating film 60 are not limited to the examples illustrated in FIGS. 3 and 4 and are arbitrary. In addition, the inter-layer insulating film 60 may also be provided on the gate electrode 13.

Next, the planar structure of the semiconductor device 1 according to the present embodiment will be described in more detail with reference to FIG. 2.

As illustrated in FIG. 2, in the present embodiment, the FP insulating film 40 has a hexagonal shape in a plane orthogonal to the Z axis, that is, a plane including the U axis and the V axis (UV plane). For example, the FP insulating film 41 in the FP trench FT1 has a hexagonal shape in the UV plane.

The FP trench FT2 is provided so as to be aligned with the FP trench FT1 along the U-axis direction orthogonal to the Z-axis direction. That is, the FP electrode 32 is aligned with the FP electrode 31 along the U-axis direction. In addition, the FP insulating film 42 is aligned with the FP insulating film 41 along the U-axis direction.

The FP trench FT3 is provided so as to be aligned with the FP trench FT1 along the V-axis direction orthogonal to the Z-axis direction and different from the U-axis direction. That is, the FP electrode 33 is aligned with the FP electrode 31 along the V-axis direction. In addition, the FP insulating film 43 is aligned with the FP insulating film 41 along the V-axis direction.

In addition, the FP trench FT2 is provided at a position closer to the FP trench FT1 than the FP trench FT3. That is, a distance d1 between the FP electrode 31 and the FP electrode 32 is smaller than a distance d2 between the FP electrode 31 and the FP electrode 33. The distance d1 and the distance d2 are examples of a first distance and a second distance, respectively, in the claims.

In the example of FIG. 2, the distance d1 is defined by a distance between a center C of the FP electrode 31 and a center C of the FP electrode 32 in the UV plane. In addition, the distance d2 is defined by a distance between the center C of the FP electrode 31 and a center C of the FP electrode 33 in the UV plane. Note that the definitions of the distance d1 and the distance d2 are not limited to those described above. For example, the distance d1 may be defined by a distance between an end of the FP electrode 31 and an end of the FP electrode 32 in the UV plane.

In addition, the first portion 41a of the FP insulating film 41 is located on a line connecting the FP electrode 31 and the FP electrode 32. The second portion 41b of the FP insulating film 41 is located on a line connecting the FP electrode 31 and the FP electrode 33. That is, the first portion 41a of the FP insulating film 41 is located on a side portion of the FP insulating film 41 in the UV plane. In addition, the second portion 41b of the FP insulating film 41 is located at a corner of the FP insulating film 41 in the UV plane. Note that the planar shapes of the first portion 40a and the second portion 40b are not limited to the example illustrated in FIG. 2 and are arbitrary. For example, the width of the first portion 40a may be larger or smaller than that of the example illustrated in FIG. 2.

In addition, the positions of the first portion 41a and the second portion 41b of the FP insulating film 41 are also related to the gate electrode 13 as follows. That is, the gate electrode 13 extends by at least a predetermined length along the direction orthogonal to the Z-axis direction. For example, in FIG. 2, the gate electrode 13 between the FP insulating film 41 and the FP insulating film 42 extends by at least a predetermined length along the direction orthogonal to the U-axis direction. In this direction, a position P1 and a position P2 having different distances from the FP insulating film 41 exist in the gate electrode 13. More specifically, a distance between the FP electrode 31 and the position P1 of the gate electrode 13 is smaller than a distance between the FP electrode 31 and the position P2 of the gate electrode 13. The first portion 41a of the FP insulating film 41 is located on a line connecting the FP electrode 31 and the position P1, and the second portion 41b of the FP insulating film 41 is located on a line connecting the FP electrode 31 and the position P2. In the example of FIG. 2, the position P1 corresponds to a position closest to the center C of the FP electrode 31 in the gate electrode 13 between the FP insulating films 41 and 42. In addition, the position P2 corresponds to a position farthest from the center C in the gate electrode 13 between the FP insulating films 41 and 42. In other words, for example, the position P2 is located at the geometric center of gravity of the FP electrodes 31 and 32 and the FP electrode 30 illustrated below the FP electrode 32 in FIG. 2. The position P1 is an example of a first position in the claims. The position P2 is an example of a second position in the claims.

As described above, the semiconductor device 1 according to the present embodiment includes the FP insulating film 41 provided in a columnar shape in the drift region 21 and having the FP electrode 31 disposed therein, the FP insulating film 42 provided in a columnar shape in the drift region 21, having the FP electrode 32 disposed therein, and aligned with the FP insulating film 41 along the U-axis direction orthogonal to the Z-axis direction from the lower surface 2a toward the upper surface 2b of the semiconductor layer 2, and the FP insulating film 43 provided in a columnar shape in the drift region 21, having the FP electrode 33 disposed therein, and aligned with the FP insulating film 41 along the V-axis direction orthogonal to the Z-axis direction and different from the U-axis direction. The distance d1 between the FP electrode 31 and the FP electrode 32 is smaller than the distance d2 between the FP electrode 31 and the FP electrode 33. The FP insulating film 41 includes the first portion 41a located on a line connecting the FP electrode 31 and the FP electrode 32 and the second portion 42b located on a line connecting the FP electrode 31 and the FP electrode 33. The dielectric constant of the second portion 42b in the FP insulating film 41 is higher than the dielectric constant of the first portion 41a in the FP insulating film 41.

According to the present embodiment, the breakdown voltage of the semiconductor device 1 can be improved. Hereinafter, functions and effects of the present embodiment will be described.

In general, in the semiconductor device including dot-patterned FP electrodes, when a reverse bias is applied between the drain electrode 11 and the source electrode 12, a depletion layer extending from the FP insulating film 40 around the FP electrode 30 to the drift region 21 is formed earlier in a portion close to the FP electrode 30, and the arrival of the depletion layer (depletion) is delayed in a portion far from the FP electrode 30. For example, at a certain point of time, the depletion layer from the FP electrode 31 (32) reaches the lower side in the Z-axis direction of the position P1 illustrated in FIG. 2. On the other hand, the depletion layer from the FP electrode 31 does not yet reach the lower side of the position P2 in the Z-axis direction. As described above, when a difference occurs in the arrival of the depletion layer, the electric field concentrates on a portion not depleted, and the breakdown voltage of the semiconductor device 1 decreases.

On the other hand, according to the semiconductor device 1 according to the present embodiment, the dielectric constant of the second portion 40b in the FP insulating film 40 is higher than the dielectric constant of the first portion 40a in the FP insulating film 40. Thereby, in a region of the drift region 21 in contact with the second portion 40b, the formation of a depletion layer is promoted more than in a region in contact with the first portion 40a. As a result, it is possible to suppress the occurrence of the difference in the arrival of the depletion layer depending on the position in the drift region 21. Therefore, the breakdown voltage of the semiconductor device 1 can be improved.

In addition, the above effect can be obtained without reducing the impurity concentration in the drift region 21. Therefore, according to the present embodiment, the breakdown voltage of the semiconductor device 1 can be improved without reducing the impurity concentration in the drift region 21. That is, the trade-off between the breakdown voltage and the on-resistance in the semiconductor device 1 can be improved.

In addition, in the present embodiment, when the third portion 40c is provided below the second portion 40b, the leakage characteristics of the semiconductor device 1 can be improved.

Note that, in the above example, the second portions 40b are provided at all the corners of the FP insulating film 40 in the UV plane. The present invention is not limited thereto, and the second portion 40b may be provided at at least one corner of the FP insulating film 40. In this case, a corner where the second portion 40b is not provided is made of, for example, the same material as the first portion 40a.

### <Method for Manufacturing Semiconductor Device 1>

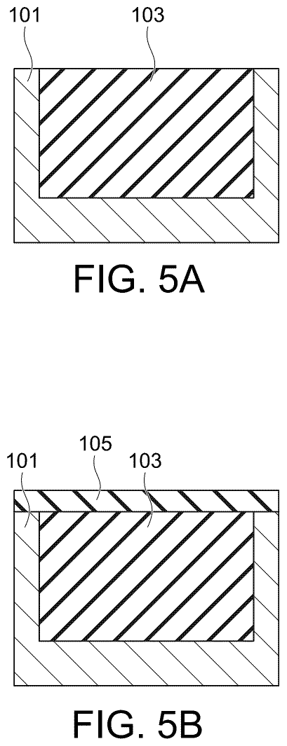

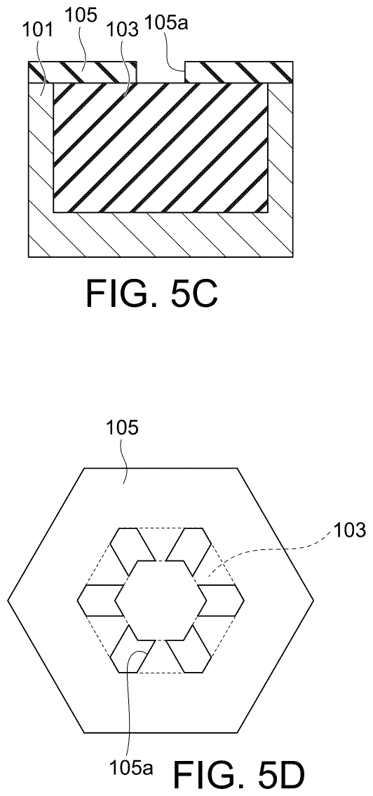

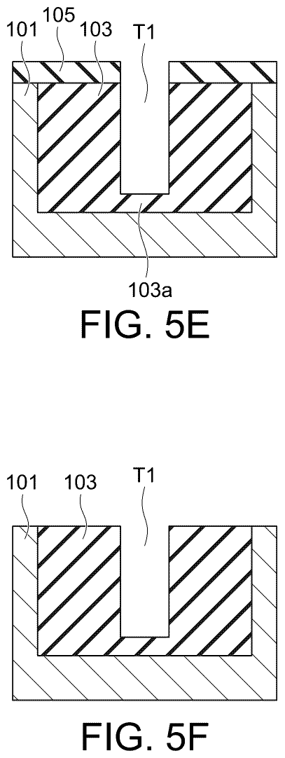

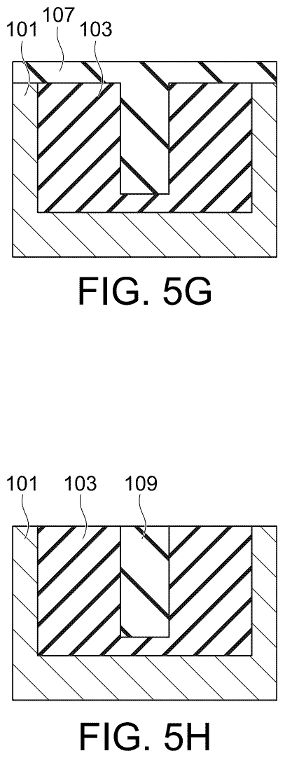

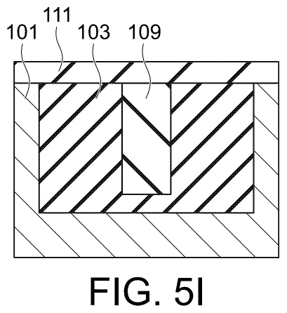

Next, an example of a method for manufacturing the semiconductor device 1 according to the present embodiment will be described with reference to FIGS. 5A to 5I. FIGS. 5A to 5C and FIGS. 5E to 5I are cross-sectional views for explaining an example of a manufacturing process of the semiconductor device 1 according to the first embodiment, taken along line A-A in FIG. 2. FIG. 5D is a schematic plan view of the semiconductor device 1 according to the first embodiment in the manufacturing process illustrated in FIG. 5C.

First, a semiconductor layer illustrated in FIG. 5A is prepared. The semiconductor layer includes a semiconductor region 101 of a first conductivity type and an insulating region 103. The semiconductor region 101 corresponds to the drift region 21. The insulating region 103 corresponds to the FP insulating film 40. The insulating region 103 is, for example, a silicon oxide film. Note that, in the semiconductor region 101, a plurality of insulating regions 103 each corresponding to at least the FP insulating films 41, 42, and 43 are provided. The planar shape and the positional relationship of the plurality of insulating regions 103 are similar to those of the FP insulating films 41, 42, and 43. Although not illustrated, the FP electrode 30 is disposed inside each insulating region 103.

Next, as illustrated in FIG. 5B, an insulating material is deposited on the upper surface of the semiconductor layer by chemical vapor deposition (CVD), for example, reduced pressure CVD (LPCVD) or the like, thereby forming an insulating region 105. The insulating material is, for example, silicon nitride, and the insulating region 105 is a silicon nitride film.

Next, as illustrated in FIG. 5C, an opening 105a is formed in the insulating region 105 by photolithography, reactive ion etching (RIE), and the like. As illustrated in FIG. 5D, the opening 105a is formed so as to be located on a corner of the insulating region 103.

Next, as illustrated in FIG. 5E, a trench T1 is formed in the insulating region 103 by RIE or the like using the insulating region 105 as a mask (hard mask). In the present embodiment, the trench T1 is formed by removing from the upper surface of the semiconductor layer to partway through at least the insulating region 103. As a result, an insulating region 103a that is a part of the insulating region 103 remains at the bottom of the trench T1. The insulating region 103a corresponds to the third portion 40c (for example, the third portion 41c).

Next, as illustrated in FIG. 5F, the insulating region 105 is removed by wet etching or the like. Note that, when the insulating region 105 is made of the same material as an insulating region 107 described later, this step may be omitted.

Next, as illustrated in FIG. 5G, an insulating material is deposited on the upper surface of the semiconductor layer using LPCVD or the like. As a result, the insulating region 107 that fills the trench T1 and covers the upper surface of the semiconductor layer is formed. The insulating material is a material having a dielectric constant higher than that of the silicon oxide film, and is, for example, silicon nitride. In addition, the insulating region 107 is, for example, a silicon nitride film.

Next, as illustrated in FIG. 5H, a portion of the insulating region 107 above the upper surface of the semiconductor layer is removed by wet etching or the like. More specifically, a portion located on the semiconductor region 101, a portion located on the insulating region 103, and a portion protruding upward from the trench T1 of the insulating region 107 are removed. As a result, a portion of the insulating region 107 that fills the trench T1 remains as an insulating region 109. The insulating region 109 corresponds to the second portion 40b (for example, the second portion 41b). In addition, portions of the insulating region 103 located on both sides of the insulating region 109 correspond to the first portion 40a (for example, the first portion 41a).

Next, as illustrated in FIG. 5I, an insulating material is deposited on the upper surface of the semiconductor layer by CVD or the like to form an insulating region 111. The insulating material is, for example, silicon oxide, and the insulating region 111 is a silicon oxide film. The insulating region 111 corresponds to the inter-layer insulating film 60.

Thereafter, although not illustrated, the gate electrode 13 and the gate insulating film 50 are formed on the upper surface of the semiconductor layer by RIE, CVD, and the like. In addition, p-type impurities are ion-implanted into the upper surface of the semiconductor layer to form the base region 23. Thereafter, n-type impurities are ion-implanted into the upper surface of the semiconductor layer to form the source region 24. Thereafter, n-type impurities are ion-implanted into the lower surface of the semiconductor layer to form the drain region 22. Thereafter, the drain electrode 11 is formed on the lower surface of the semiconductor layer, and the source electrode 12 is formed on the upper surface of the semiconductor layer.

Through the above steps, the semiconductor device 1 is manufactured.

Note that, in the method for manufacturing the semiconductor device 1 described above, the trench T1 was formed, the trench T1 was filled with the insulating region 109, and then the base region 23 and the source region 24 were formed. The present invention is not limited thereto, and the trench T1 may be formed after the base region 23 and the source region 24 are formed, and the trench T1 may be filled with the insulating region 109.

### Modification of First Embodiment

In the manufacturing method of the first embodiment described above, a portion of the insulating region 107 above the upper surface of the semiconductor layer was removed in the step illustrated in FIG. 5H. The present invention is not limited thereto, and the step may be omitted. Hereinafter, a modification of the first embodiment in which the step is omitted in the manufacturing method of the first embodiment will be described focusing on differences from the first embodiment.

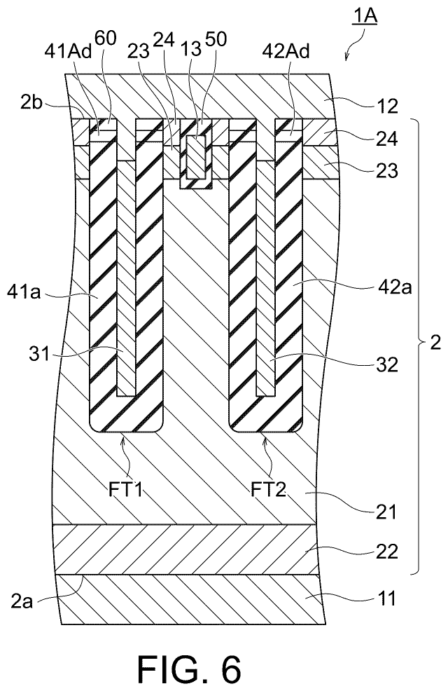

FIG. 6 is a cross-sectional view of a semiconductor device 1A according to a modification of the first embodiment, taken along the U-axis direction in FIG. 1. As illustrated in FIG. 6, in the present modification, the FP insulating film 40 further includes a fourth portion 40Ad located on the first portion 40a. That is, the fourth portion 40Ad is provided between the first portion 40a and the inter-layer insulating film 60. In FIG. 6, as the fourth portion 40Ad, a fourth portion 41Ad of the FP insulating film 41 and a fourth portion 42Ad of the FP insulating film 42 are illustrated. The fourth portion 40Ad includes a silicon nitride film. Although not illustrated, the fourth portion 40Ad may also be provided on at least one of the source region 24 and the gate insulating film 50.

### <Method for Manufacturing Semiconductor Device 1A>

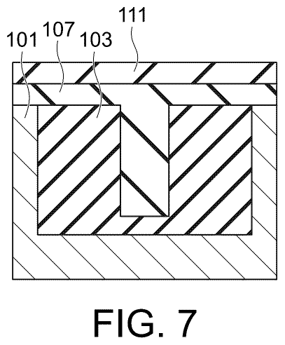

FIG. 7 is a cross-sectional view for explaining an example of a manufacturing process of the semiconductor device 1 according to a modification of the first embodiment, corresponding to a cross-sectional view taken along line A-A in FIG. 2.

As illustrated in FIG. 7, in the present modification, after the insulating region 107 is formed, the insulating region 111 corresponding to the inter-layer insulating film 60 is formed without removing a part of the insulating region 107. Note that, when the fourth portion 40Ad is not provided on the source region 24 and the gate insulating film 50, a portion of the insulating region 107 located on the semiconductor region 101 is removed before the insulating region 111 is formed.

The subsequent steps are similar to those in the first embodiment.

According to the method for manufacturing the semiconductor device 1A according to the present modification, it is possible to suppress moisture from entering the semiconductor layer from the insulating region 111 which is an inter-layer insulating film. Therefore, according to the present modification, the reliability of the semiconductor device 1A can be improved.

### Second Embodiment

In the above-described first embodiment, a silicon oxide film was provided in the first portion 40a of the FP insulating film 40, and a material having a dielectric constant higher than that of the silicon oxide film was provided in the second portion 40b. On the other hand, in the second embodiment described below, a silicon oxide film is provided in the second portion 40b of the FP insulating film 40, and a material having a dielectric constant lower than that of the silicon oxide film is provided in the first portion 40a. Hereinafter, the second embodiment will be described focusing on the differences from the first embodiment.

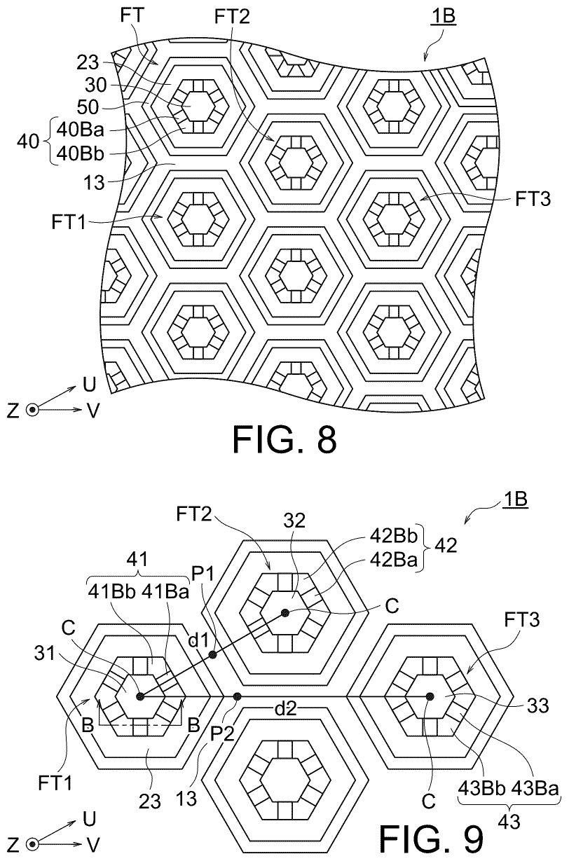

FIG. 8 is a plan view of a semiconductor device 1B according to a second embodiment. FIG. 9 is an enlarged view of FIG. 8, and illustrates the periphery of the FP trenches FT1, FT2, and FT3 in an enlarged manner. As illustrated in FIGS. 8 and 9, in the present embodiment, a second portion 40Bb of the FP insulating film 40 is a silicon oxide film, and a first portion 40Ba of the FP insulating film 40 is made of a material having a dielectric constant lower than that of the silicon oxide film. The first portion 40Ba includes, for example, a spin-on-glass film (SOG film). The material of the SOG film is silica glass, an alkylsiloxane polymer, an alkylsilsesquioxane polymer, a hydrogenated silsesquioxane polymer, a hydrogenated alkylsilsesquioxane polymer, or the like. In this case, for example, the relative permittivity of the first portion 41Ba is about 2.9, and the relative permittivity of the second portion 40Bb is about 3.9.

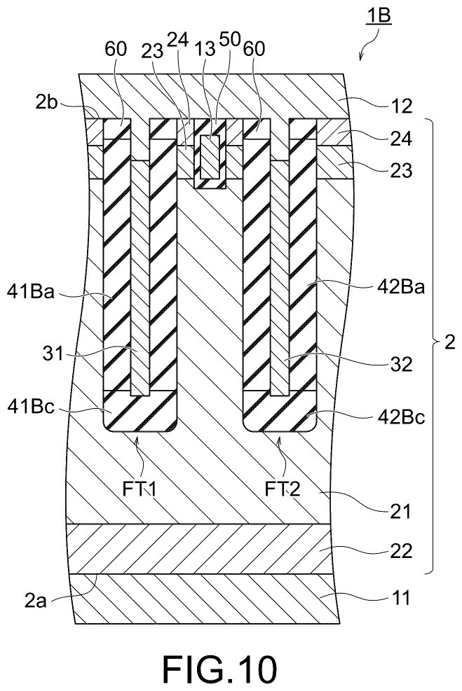

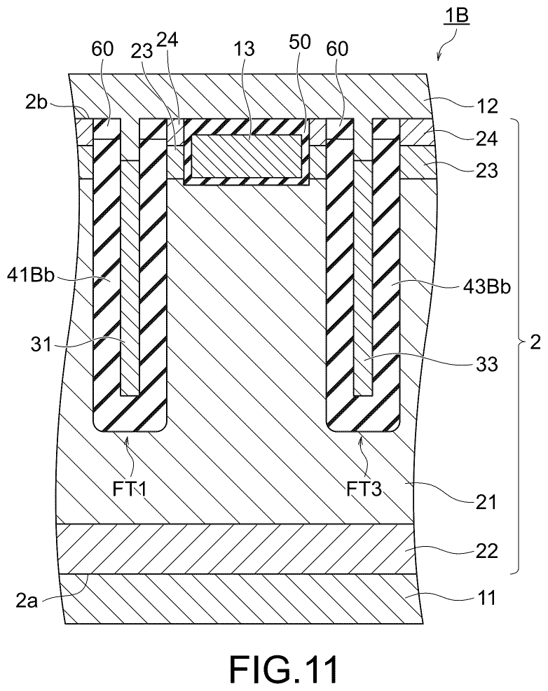

FIG. 10 is a cross-sectional view of the semiconductor device 1B according to the second embodiment, taken along a U-axis direction in FIG. 8. FIG. 11 is a cross-sectional view of the semiconductor device 1B according to the second embodiment, taken along a V-axis direction in FIG. 8. As illustrated in FIG. 10, in the present embodiment, a fifth portion 40Bc located below the first portion 40Ba and disposed on the drift region 21 is provided. In FIG. 10, as the fifth portion 40Bc of the FP insulating film 40, a fifth portion 41Bc of the FP insulating film 41 and a fifth portion 42Bc of the FP insulating film 42 are illustrated. The fifth portion 40Bc is made of, for example, the same material as the second portion 40Bb. The fifth portion 40Bc is, for example, a silicon oxide film.

In the present embodiment, contrary to the first embodiment, in a region of the drift region 21 in contact with the first portion 40Ba, formation of a depletion layer is suppressed more than in a region in contact with the second portion 40Bb. As a result, similarly to the first embodiment, it is possible to suppress the occurrence of the difference in the arrival of the depletion layer depending on the position in the drift region 21. Therefore, the breakdown voltage of the semiconductor device 1B can be improved.

In addition, in the present embodiment, when the fifth portion 40Bc is provided below the first portion 41Ba, the leakage characteristics of the semiconductor device 1B can be improved.

Note that, in the above example, the first portions 40Ba are provided at all the corners of the FP insulating film 40 in the UV plane. The present invention is not limited thereto, and the first portion 40Ba may be provided on at least one side portion of the FP insulating film 40. In this case, a corner where the first portion 40Ba is not provided is made of, for example, the same material as the second portion 40Bb.

In addition, the present embodiment may be combined with the first embodiment. For example, in the UV plane, a first portion made of a material having a dielectric constant lower than that of a silicon oxide film may be provided at a side portion of the FP insulating film 40, a second portion made of a material having a dielectric constant higher than that of a silicon oxide film may be provided at a corner of the FP insulating film 40, and a portion that is a silicon oxide film may be provided between the first portion and the second portion.

### <Method for Manufacturing Semiconductor Device 1B>

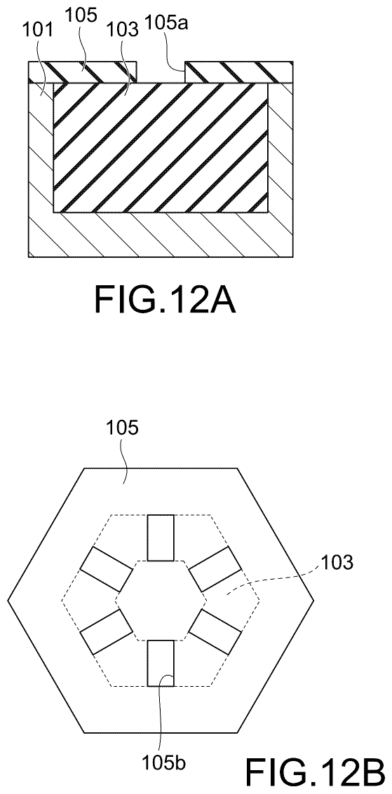

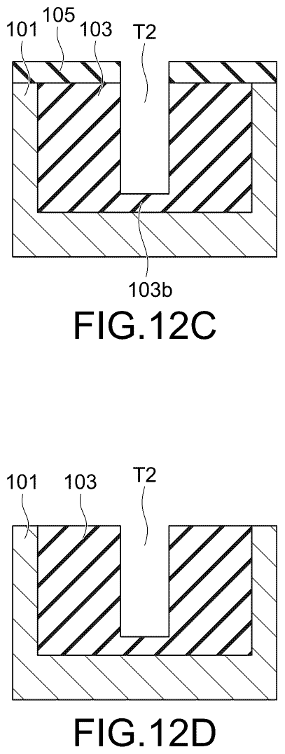

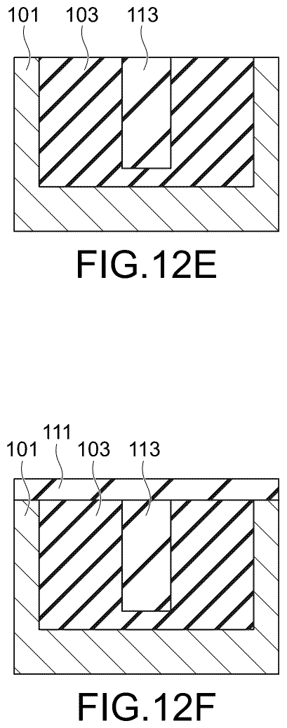

Next, an example of a method for manufacturing the semiconductor device 1B according to the present embodiment will be described with reference to FIGS. 12A to 12F. FIG. 12A and FIGS. 12C to 12F are cross-sectional views for explaining an example of a manufacturing process of the semiconductor device 1B according to the second embodiment, taken along line B-B in FIG. 9. FIG. 12B is a schematic plan view of the semiconductor device 1B according to the second embodiment in the manufacturing process illustrated in FIG. 12A.

First, similarly to the manufacturing method of the first embodiment, a semiconductor layer including the semiconductor region 101 of the first conductivity type and the insulating region 103 is prepared. Thereafter, an insulating material is deposited on the upper surface of the semiconductor layer using LPCVD or the like to form the insulating region 105.

Next, as illustrated in FIG. 12A, an opening 105b is formed in the insulating region 105 by photolithography, RIE, and the like. As illustrated in FIG. 12B, the opening 105b is formed so as to be located on a side portion of the insulating region 103.

Next, as illustrated in FIG. 12C, a trench T2 is formed in the insulating region 103 by RIE or the like using the insulating region 105 as a mask. In the present embodiment, the trench T2 is formed such that an insulating region 103b that is a part of the insulating region 103 remains at the bottom of the trench T2. The insulating region 103b corresponds to the fifth portion 40Bc (for example, the fifth portion 41Bc).

Next, as illustrated in FIG. 12D, the insulating region 105 is removed by wet etching or the like.

Next, as illustrated in FIG. 12E, the trench T2 is filled with a material having a dielectric constant lower than that of a silicon oxide film. For example, an insulating region for filling the trench T2 is formed by using a spin-on-glass method or the like. Thereafter, a portion of the insulating region above the upper surface of the semiconductor layer is removed by wet etching or the like. As a result, an insulating region 113 filling the trench T2 is formed. The insulating region 113 corresponds to the first portion 40Ba (for example, the first portion 41Ba). In addition, portions of the insulating region 103 located on both sides of the insulating region 113 correspond to the second portion 40Bb (for example, a second portion 41Bb).

Next, as illustrated in FIG. 12F, an insulating material is deposited by CVD or the like to form the insulating region 111. The subsequent steps are similar to those in the first embodiment.

Through the above steps, the semiconductor device 1B is manufactured.

### Third Embodiment

In the above-described second embodiment, a material having a dielectric constant lower than that of the silicon oxide film is provided in the first portion 40Ba of the FP insulating film 40. The present invention is not limited thereto, and the first portion of the FP insulating film may be a gap. The gap has a dielectric constant lower than that of the silicon oxide film. Hereinafter, a third embodiment in which the first portion is a gap will be described focusing on the differences from the second embodiment.

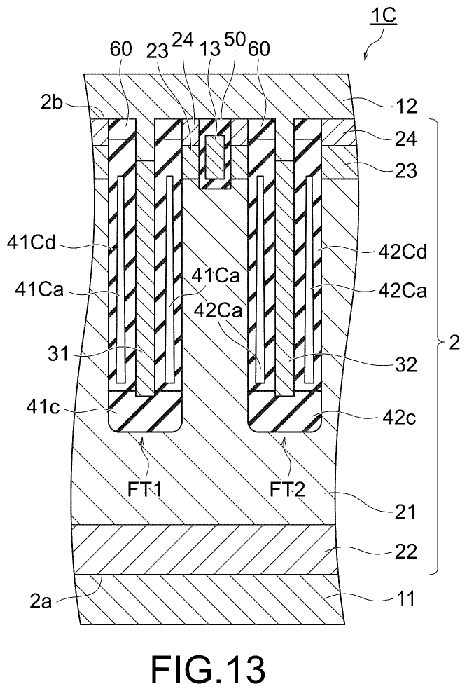

FIG. 13 is a cross-sectional view of a semiconductor device 1C according to a third embodiment, taken along the U-axis direction in FIG. 8. As illustrated in FIG. 13, in the present embodiment, a first portion 40Ca of the FP insulating film 40 is a gap. In FIG. 13, as the first portion 40Ca of the FP insulating film 40, a first portion 41Ca of the FP insulating film 41 and a first portion 42Ca of the FP insulating film 42 are illustrated.

In addition, in the present embodiment, the FP insulating film 40 includes a sixth portion 40Cd surrounding the first portion 40Ca. In FIG. 13, as the sixth portion 40Cd of the FP insulating film 40, a sixth portion 41Cd of the FP insulating film 41 and a sixth portion 42Cd of the FP insulating film 42 are illustrated. The sixth portion 40Cd is made of, for example, the same material as the inter-layer insulating film 60. Specifically, the sixth portion 40Cd is, for example, a silicon oxide film. Note that the sixth portion 40Cd may be made of a material having a dielectric constant lower than that of the silicon oxide film.

According to the present embodiment, similarly to the first embodiment and the second embodiment, it is possible to suppress the occurrence of the difference in the arrival of the depletion layer depending on the position in the drift region 21, and to improve the breakdown voltage of the semiconductor device 1C.

### <Method for Manufacturing Semiconductor Device 1C>

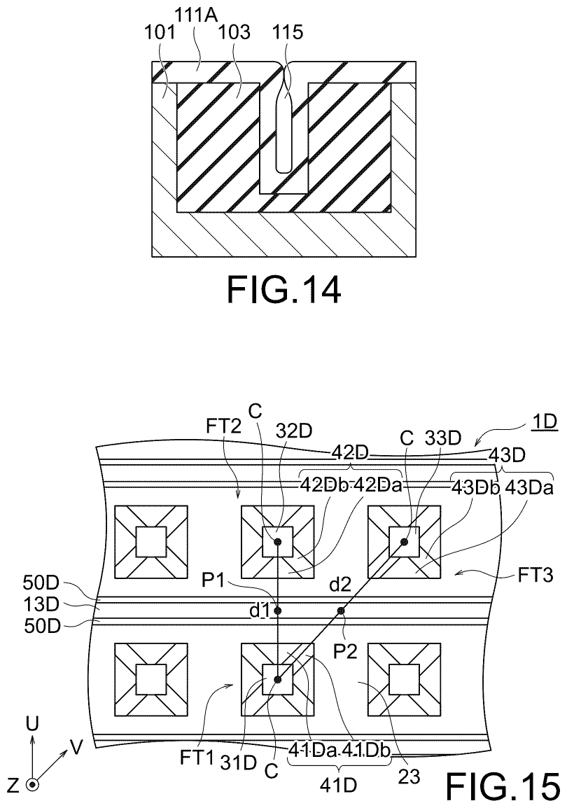

Next, an example of a method for manufacturing the semiconductor device 1C according to the present embodiment will be described with reference to FIG. 14. FIG. 14 is a cross-sectional view for explaining an example of a manufacturing process of the semiconductor device 1C according to the third embodiment, corresponding to a cross-sectional view taken along line B-B in FIG. 9.

As illustrated in FIG. 14, in the present embodiment, when an insulating material is deposited using CVD or the like after the trench T2 is formed, an insulating region 111A is formed such that a gap 115 is formed in the trench T2. The insulating material is, for example, silicon oxide, and the insulating region 111A is a silicon oxide film. The insulating region 111A corresponds to the sixth portion 40Cd (for example, the sixth portion 41Cd) and the inter-layer insulating film 60. More specifically, a portion of the insulating region 111A sandwiched between the insulating regions 103 corresponds to the sixth portion 40Cd, and a portion located on the insulating region 103 corresponds to the inter-layer insulating film 60. In addition, the gap 115 corresponds to the first portion 40Ca (for example, the first portion 41Ca). The subsequent steps are similar to those in the second embodiment.

Through the above steps, the semiconductor device 1C is manufactured.

In the above-described first to third embodiments, the FP insulating film 40 (for example, the FP insulating film 41) had a hexagonal shape in the UV plane. The present invention is not limited thereto, and the shape of the FP insulating film 40 in the UV plane is not limited to a hexagonal shape as long as the distance between the FP electrode 30 and the gate electrode 13 changes. Hereinafter, other Modifications 1 to 5 of the embodiment in which the shape of the FP insulating film 40 in the UV plane is changed will be described. Note that, in any of the modifications, it is possible to suppress the occurrence of the difference in the arrival of the depletion layer depending on the position in the drift region 21, and to improve the breakdown voltage of the semiconductor device.

### Other Modification 1 of Embodiment

FIG. 15 is a plan view of a semiconductor device 1D according to other Modification 1 of the embodiment. The present modification corresponds to a case where the above-described first embodiment is applied to an FP insulating film 40D having a quadrangular shape. Hereinafter, the present modification will be described focusing on the differences from the first embodiment.

As illustrated in FIG. 15, in the present modification, the FP insulating film 40D (for example, an FP insulating film 41D) has a quadrangular shape in the UV plane. An FP electrode 30D having a quadrangular shape (for example, an FP electrode 31D) is provided in each FP insulating film 40D.

In the present modification, a gate electrode 13D and a gate insulating film 50D have a stripe shape. That is, the gate electrode 13D and the gate insulating film 50D extend by at least a predetermined length along the direction orthogonal to the Z-axis direction.

In addition, in the present modification, a first portion 40Da (for example, a first portion 41Da) of the FP insulating film 40D is located on a side portion of the FP insulating film 40D in the UV plane. A second portion 40Db (for example, a second portion 41Db) of the FP insulating film 40D is located at a corner of the FP insulating film 40D in the UV plane.

In addition, in the present modification, the positions of the first portion 41Da and the second portion 41Db of the FP insulating film 41D are also related to the gate electrode 13D as follows. For example, in FIG. 15, the gate electrode 13D between the FP insulating films 41D and 42D extends by at least a predetermined length along the direction orthogonal to the U-axis direction. A distance between the FP electrode 31D and a position P1 of the gate electrode 13D is smaller than a distance between the FP electrode 31D and a position P2 of the gate electrode 13D.

According to the present modification, the configuration of the first embodiment can also be applied to the FP insulating film 40D having a quadrangular shape. Note that portions of the first portion 40Da sandwiching the FP electrode 30D along the extending direction of the gate electrode 13D (for example, the first portions 41Da located on the right and left of the FP electrode 31D in FIG. 15) may be replaced with the second portion 40Db.

### Other Modification 2 of Embodiment

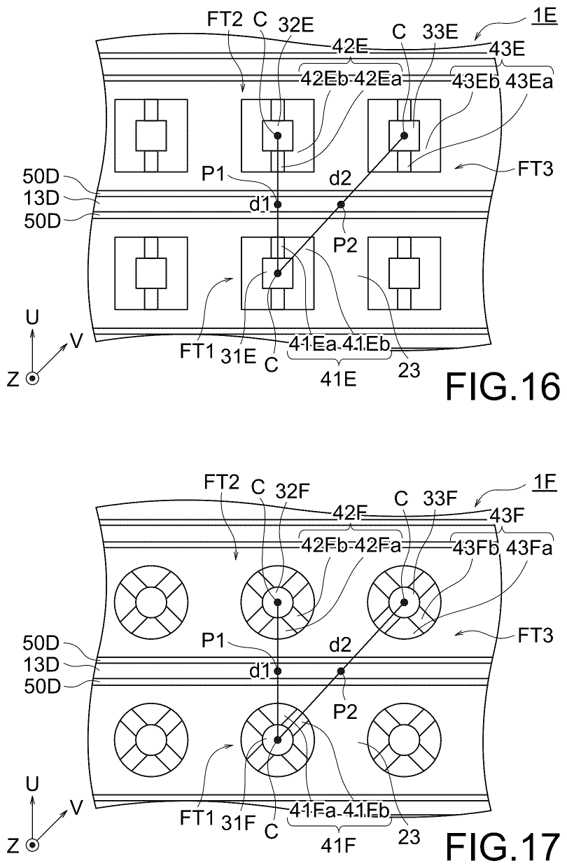

FIG. 16 is a plan view of a semiconductor device 1E according to other Modification 2 of the embodiment. The present modification corresponds to a case where the second embodiment is applied to an FP insulating film having a quadrangular shape. That is, the present modification corresponds to a case where the configuration of the FP insulating film in the second embodiment is applied to other Modification 1 of the embodiment. Hereinafter, the present modification will be described focusing on the differences from other Modification 1 of the embodiment.

As illustrated in FIG. 16, in the present modification, a first portion 40Ea (for example, a first portion 41Ea) of an FP insulating film 40E (for example, the FP insulating film 41E) is located on a side portion of the FP insulating film 40E in the UV plane. A second portion 40Eb (for example, a second portion 41Eb) of the FP insulating film 40E is located at a corner of the FP insulating film 40E in the plane.

According to the present modification, the configuration of the second embodiment can also be applied to the FP insulating film 40E having a quadrangular shape.

### Other Modification 3 of Embodiment

FIG. 17 is a plan view of a semiconductor device 1F according to other Modification 3 of the embodiment. The present modification corresponds to a case where other Modification 1 of the embodiment is applied to an FP insulating film 40F having a circular shape. Hereinafter, the present modification will be described focusing on the differences from other Modification 1 of the embodiment.

As illustrated in FIG. 16, in the present modification, the FP insulating film 40F (for example, an FP insulating film 41F) has a circular shape in the UV plane. An FP electrode 30F having a circular shape (for example, an FP electrode 31F) is provided in the FP insulating film 40F.

In the present modification, a first portion 40Fa and a second portion 40Fb of the FP insulating film 40F (for example, a first portion 41Fa and a second portion 41Fb of the FP insulating film 41F) are alternately arranged along the circumferential direction of the FP insulating film 40F in the UV plane. However, for example, the first portion 41Fa is located on a line connecting the FP electrode 31F and an FP electrode 32F, and the second portion 41Fb is located on a line connecting the FP electrode 31F and an FP electrode 33F.

According to the present modification, the configuration of the first embodiment can also be applied to the FP insulating film 40F having a circular shape. Note that portions of the first portion 40Fa sandwiching the FP electrode 30F along the extending direction of the gate electrode 13F (for example, the first portions 41Fa located on the right and left of the FP electrode 31F in FIG. 17) may be replaced with the second portion 40Fb. Alternatively, the present modification may be applied to the configuration of the second embodiment.

### Other Modification 4 of Embodiment

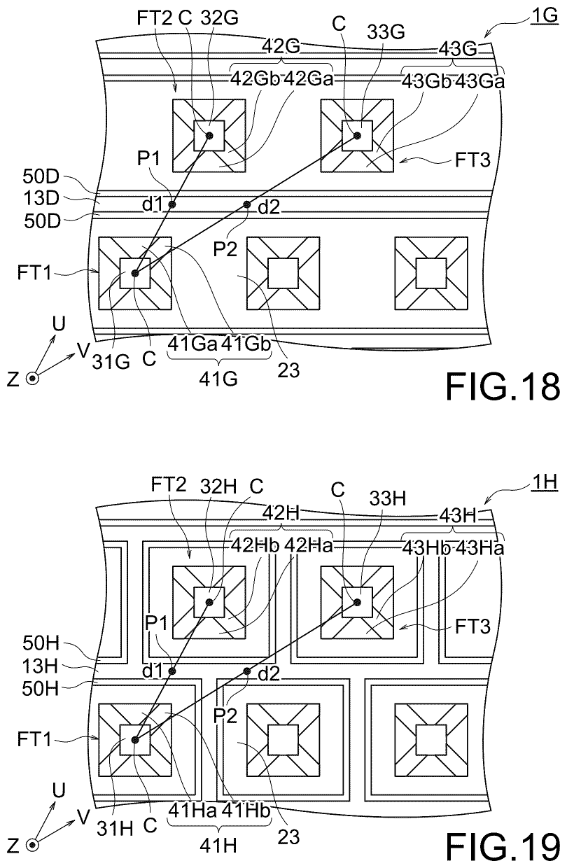

FIG. 18 is a plan view of a semiconductor device 1G according to other Modification 4 of the embodiment. The present modification corresponds to a case where the FP insulating film 40D having a quadrangular shape is arranged offset along the extending direction of the gate electrode 13D in other Modification 1 of the embodiment. Also in the present modification, similarly to other Modification 1 of the embodiment, an FP insulating film 40G (for example, an FP insulating film 41G) includes a first portion 40Ga and a second portion 40Gb (for example, a first portion 41Ga and a second portion 41Gb).

According to the present modification, the configuration of the first embodiment can also be applied to the FP insulating film 40G arranged offset. Note that the present modification may be applied to the configuration of the second embodiment or may be applied to the FP insulating film having a circular shape.

### Other Modification 5 of Embodiment

FIG. 19 is a plan view of a semiconductor device 1H according to other Modification 5 of the embodiment. The present modification corresponds to a case where a mesh-shaped gate electrode is provided in other Modification 4 of the embodiment. Hereinafter, the present modification will be described focusing on the differences from other Modification 4 of the embodiment.

In the present modification, a gate insulating film 50H is disposed so as to surround an FP insulating film 40H (for example, an FP insulating film 41H). In addition, a mesh-shaped gate electrode 13H coupled to each other is provided around the gate insulating film 50H.

According to the present modification, the configuration of the first embodiment can also be applied to the semiconductor device 1H having the gate electrode 13H provided in a quadrangular mesh shape. Note that the present modification may be applied to the configuration of the second embodiment. Alternatively, an FP insulating film having a circular shape may be provided inside the gate electrode 13H provided in a quadrangular mesh shape.

### Other Modifications

In the embodiments and the modifications described above, all the FP trenches FT had the same configuration. Note that at least one FP trench FT may have a configuration different from another FP trench FT. For example, while the FP insulating films 41 and 42 in the FP trenches FT1 and FT2 have the same configuration as that of the first embodiment, the FP insulating film 43 in the FP trench FT3 may have the first portion 43a and the second portion 43b which are made of the same material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer including a first main surface and a second main surface;
a first electrode provided on the first main surface;
a second electrode provided on the second main surface;
a first semiconductor region of a first conductivity type provided in the semiconductor layer and electrically connected to the first electrode;
a second semiconductor region of a second conductivity type provided in the semiconductor layer and located on the first semiconductor region;
a third semiconductor region of the first conductivity type provided in the semiconductor layer and located on the second semiconductor region;
a gate electrode provided in the second semiconductor region via a gate insulating film;
a first field plate insulating film provided in a columnar shape in the first semiconductor region and having a first field plate electrode disposed therein;
a second field plate insulating film provided in a columnar shape in the first semiconductor region, having a second field plate electrode disposed therein, and aligned with the first field plate insulating film along a second direction orthogonal to a first direction from the first main surface toward the second main surface; and
a third field plate insulating film provided in a columnar shape in the first semiconductor region, having a third field plate electrode disposed therein, and aligned with the first field plate insulating film along a third direction orthogonal to the first direction and different from the second direction, wherein
a first distance between the first field plate electrode and the second field plate electrode is smaller than a second distance between the first field plate electrode and the third field plate electrode,
the first field plate insulating film includes a first portion located on a line connecting the first field plate electrode and the second field plate electrode, and a second portion located on a line connecting the first field plate electrode and the third field plate electrode, and
a dielectric constant of the second portion in the first field plate insulating film is higher than a dielectric constant of the first portion in the first field plate insulating film.

2. The semiconductor device according to claim 1, wherein
the first portion of the first field plate insulating film is a silicon oxide film, and
the second portion of the first field plate insulating film is made of a material having a dielectric constant higher than that of the silicon oxide film.

3. The semiconductor device according to claim 2, wherein
the first field plate insulating film has a hexagonal shape in a plane orthogonal to the first direction,
the first portion of the first field plate insulating film is located on a side portion of the first field plate insulating film in the plane, and
the second portion of the first field plate insulating film is located at a corner of the first field plate insulating film in the plane.

4. The semiconductor device according to claim 2, wherein the second portion of the first field plate insulating film includes a silicon nitride film.

5. The semiconductor device according to claim 2, wherein the first field plate insulating film further includes a third portion that is located below the second portion of the first field plate insulating film, wherein the third portion is disposed on the first semiconductor region and is a silicon oxide film.

6. The semiconductor device according to claim 5, wherein
the first field plate insulating film has a hexagonal shape in a plane orthogonal to the first direction,
the first portion of the first field plate insulating film is located on a side portion of the first field plate insulating film in the plane, and
the second portion of the first field plate insulating film is located at a corner of the first field plate insulating film in the plane.

7. The semiconductor device according to claim 2, wherein the first field plate insulating film further includes a fourth portion that is located on the first portion and includes a silicon nitride film.

8. The semiconductor device according to claim 1, wherein
the second portion of the first field plate insulating film is a silicon oxide film, and
the first portion of the first field plate insulating film is made of a material having a dielectric constant lower than that of the silicon oxide film.

9. The semiconductor device according to claim 8, wherein
the first field plate insulating film has a hexagonal shape in a plane orthogonal to the first direction,
the first portion of the first field plate insulating film is located on a side portion of the first field plate insulating film in the plane, and
the second portion of the first field plate insulating film is located at a corner of the first field plate insulating film in the plane.

10. The semiconductor device according to claim 8, wherein the first portion of the first field plate insulating film includes a spin-on-glass film.

11. The semiconductor device according to claim 8, wherein the first field plate insulating film further includes a fifth portion that is located below the first portion of the first field plate insulating film, wherein the fifth portion is disposed on the first semiconductor region and is a silicon oxide film.

12. The semiconductor device according to claim 11, wherein
the first field plate insulating film has a hexagonal shape in a plane orthogonal to the first direction,
the first portion of the first field plate insulating film is located on a side portion of the first field plate insulating film in the plane, and
the second portion of the first field plate insulating film is located at a corner of the first field plate insulating film in the plane.

13. The semiconductor device according to claim 1, wherein
the second portion of the first field plate insulating film is a silicon oxide film, and
the first portion of the first field plate insulating film is a gap.

14. The semiconductor device according to claim 13, wherein
the first field plate insulating film has a hexagonal shape in a plane orthogonal to the first direction,
the first portion of the first field plate insulating film is located on a side portion of the first field plate insulating film in the plane, and
the second portion of the first field plate insulating film is located at a corner of the first field plate insulating film in the plane.

15. The semiconductor device according to claim 1, wherein
the first field plate insulating film has a hexagonal shape in a plane orthogonal to the first direction,
the first portion of the first field plate insulating film is located on a side portion of the first field plate insulating film in the plane, and
the second portion of the first field plate insulating film is located at a corner of the first field plate insulating film in the plane.

16. The semiconductor device according to claim 1, wherein
the first field plate insulating film has a quadrangular shape in a plane orthogonal to the first direction,
the first portion of the first field plate insulating film is located on a side portion of the first field plate insulating film in the plane, and
the second portion of the first field plate insulating film is located at a corner of the first field plate insulating film in the plane.

17. The semiconductor device according to claim 1, wherein
the first field plate insulating film has a circular shape in a plane orthogonal to the first direction, and
the first portion and the second portion of the first field plate insulating film are alternately arranged along a circumferential direction of the first field plate insulating film in the plane.

18. A semiconductor device comprising:
a semiconductor layer including a first main surface and a second main surface;
a first electrode provided on the first main surface;
a second electrode provided on the second main surface;
a first semiconductor region of a first conductivity type provided in the semiconductor layer and electrically connected to the first electrode;
a second semiconductor region of a second conductivity type provided in semiconductor layer and located on the first semiconductor region;
a third semiconductor region of the first conductivity type provided in the semiconductor layer and located on the second semiconductor region;
a gate electrode provided in the second semiconductor region via a gate insulating film and extending along a direction orthogonal to a first direction from the first main surface toward the second main surface; and
a first field plate insulating film provided in a columnar shape in the first semiconductor region and having a first field plate electrode disposed therein, wherein
a distance between the first field plate electrode and a first position of the gate electrode is smaller than a distance between the first field plate electrode and a second position of the gate electrode,
the first field plate insulating film includes a first portion located on a line connecting the first field plate electrode and the first position, and a second portion located on a line connecting the first field plate electrode and the second position, and
a dielectric constant of the second portion in the first field plate insulating film is higher than a dielectric constant of the first portion in the first field plate insulating film.

19. A method for manufacturing a semiconductor device, comprising:
preparing a semiconductor layer including a first main surface and a second main surface, the semiconductor layer including
a first semiconductor region of a first conductivity type,
a first field plate insulating film provided in a columnar shape in the first semiconductor region and having a first field plate electrode disposed therein,
a second field plate insulating film provided in a columnar shape in the first semiconductor region, having a second field plate electrode disposed therein, and aligned with the first field plate insulating film along a second direction orthogonal to a first direction from the first main surface toward the second main surface, and
a third field plate insulating film provided in a columnar shape in the first semiconductor region, having a third field plate electrode disposed therein, and aligned with the first field plate insulating film along a third direction orthogonal to the first direction and different from the second direction,
in which a first distance between the first field plate electrode and the second field plate electrode is smaller than a second distance between the first field plate electrode and the third field plate electrode;
forming a trench by removing from the second main surface to partway through at least the first field plate insulating film in a portion of the first field plate insulating film located on a line connecting the first field plate electrode and the third field plate electrode; and
filling the trench with a material having a dielectric constant higher than that of a silicon oxide film.
